(19) United States
(12) Patent Application Publication
(10) Pub. No.: US 2019/0300821 A1
(43) Pub. Date: Oct. 3, 2019

(54) SURFACE TREATMENT COMPOSITION

(71) Applicant: FUJIMI INCORPORATED, Kiyosu-shi, Aichi (JP)

(72) Inventors: Yukinobu YOSHIZAKI, Kiyosu-shi, Aichi (JP); Koichi SAKABE, Kiyosu-shi, Aichi (JP); Satoru YARITA, Kiyosu-shi, Aichi (JP); Kenichi KOMOTO, Kiyosu-shi, Aichi (JP)

(73) Assignee: FUJIMI INCORPORATED, Kiyosu-shi, Aichi (JP)

(21) Appl. No.: 16/337,241

(22) PCT Filed: Jun. 29, 2017
(86) PCT No.: PCT/JP2017/023949

§ 371 Date: Mar. 27, 2019

(30) Foreign Application Priority Data
Sep. 28, 2016 (JP) 2016-190375

(51) Int. Cl. C11D 1/12; C11D 3/22; C11D 3/37; C11D 1/34; C11D 3/00

(52) U.S. Cl. CPC C11D 1/12; C11D 3/222; H01L 21/304; C11D 1/342; C11D 3/0047; C11D 3/3753

(57) ABSTRACT

The present invention relates to a surface treatment composition including:
at least one water-soluble polymer selected from the following Group A;
at least one anionic surfactant selected from the following Group B; and
water.

Group A: water-soluble polysaccharides, polyvinyl alcohols and derivatives thereof, and polyvinylpyrrolidones and derivatives thereof (with the proviso that compounds included in the following Group B are excluded)

Group B: compounds having a sulfonic acid (salt) group, compounds having a sulfuric acid ester (salt) group, compounds having a phosphonic acid (salt) group, compounds having a phosphoric acid (salt) group, and compounds having a phosphinic acid (salt) group. According to the present invention, a surface treatment composition capable of efficiently removing foreign bodies, such as particles and organic residues, remaining on the surface of an object to be polished after polishing is provided.

### TECHNICAL FIELD

The present invention relates to a surface treatment composition.

### BACKGROUND ART

In recent years, with the development of multilayer interconnection on the surface of a semiconductor substrate, in the production of devices, a technology of physically polishing and flattening the semiconductor substrate, so-called chemical mechanical polishing (CMP), has been utilized. CMP is a method for flattening the surface of an object to be polished (polishing object), such as a semiconductor substrate, using a polishing composition (slurry) containing abrasive grains such as silica, alumina, or ceria, an anticorrosive, a surfactant, and the like. The object to be polished (polishing object) is an interconnect wire, a plug, or the like made of silicon, polysilicon, silicon oxide, silicon nitride, metal, or the like.

The semiconductor substrate surface after a CMP step has remaining thereon a large amount of impurities (foreign bodies). Impurities include organic matters such as abrasive grains, metals, anticorrosives, and surfactants from the polishing composition used in CMP, silicon-containing materials and metals produced as a result of polishing silicon-containing materials, metallic interconnect wires, plugs, and the like as objects to be polished, and further organic matters such as pad debris or the like produced from various pads, for example.

When the semiconductor substrate surface is contaminated with these impurities, the electrical properties of the semiconductor may be adversely affected, resulting in a decrease in the reliability of the device. Therefore, it is desirable that a cleaning step is introduced after a CMP step to remove these impurities from the semiconductor substrate surface.

As a cleaning agent (surface treatment composition) for use in such a cleaning step, for example, JP 2006-5246 A (corresponding to the Description of U.S. Patent Application Publication No. 2005/282718) discloses a rinse composition containing a water-soluble polymer, such as a water-soluble polysaccharide, and water.

### SUMMARY OF INVENTION

However, there has been a demand for a technology, according to which particles and organic residues deposited or remaining on a semiconductor substrate surface after a CMP step can be removed more efficiently.

The present invention has been accomplished in view of the above problems, and an object thereof is to provide a surface treatment composition capable of efficiently removing foreign bodies, such as particles and organic residues, remaining on the surface of an object to be polished after polishing.

The present inventors have conducted extensive research in light of the above problems. As a result, they have found that the above problems can be solved by a surface treatment composition containing a specific water-soluble polymer, a specific anionic surfactant, and water, and thus accomplished the present invention.

That is, the above problems to be solved by the present invention can be solved by a surface treatment composition including at least one water-soluble polymer selected from the following Group A, at least one anionic surfactant selected from the following Group B, and water:

Group A: water-soluble polysaccharides, polyvinyl alcohols and derivatives thereof, and polyvinylpyrrolidones and derivatives thereof (with the proviso that compounds included in the following Group B are excluded)

Group B: compounds having a sulfonic acid (salt) group, compounds having a sulfuric acid ester (salt) group, compounds having a phosphonic acid (salt) group, compounds having a phosphoric acid (salt) group, and compounds having a phosphinic acid (salt) group.

### DESCRIPTION OF EMBODIMENTS

The surface treatment composition according to the present invention is used for cleaning the surface of an object to be polished that has been polished in a polishing step (object to be polished after polishing), and is particularly suitable for use in a rinse polishing treatment.

A cleaning step after a chemical mechanical polishing (CMP) step is performed for the purpose of removing impurities (foreign bodies such as particles, metallic contaminants, organic residues, and pad debris) remaining on the surface of a semiconductor substrate (object to be polished after polishing). At this time, these foreign bodies can be removed by cleaning using, for example, the cleaning agent disclosed in JP 2006-5246 A (corresponding to US 2005/282718 A). However, in order to achieve more efficient removal of foreign bodies, the present inventors have conducted extensive research. As a result, they have found that when the surface treatment composition according to the present invention is used, foreign bodies, such as particles and organic residues, are removed extremely efficiently.

The surface treatment composition according to the present invention includes at least one water-soluble polymer selected from the following Group A, at least one anionic surfactant selected from the following Group B, and water:

Group A: water-soluble polysaccharides, polyvinyl alcohols and derivatives thereof, and polyvinylpyrrolidones and derivatives thereof (with the proviso that compounds included in the following Group B are excluded)

Group B: compounds having a sulfonic acid (salt) group, compounds having a sulfuric acid ester (salt) group, compounds having a phosphonic acid (salt) group, compounds having a phosphoric acid (salt) group, and compounds having a phosphinic acid (salt) group.

With respect to the mechanism that the above problems are solved by the present invention, the present inventors suppose as follows.

The hydrophilicity/hydrophobicity of the surface of an object to be polished after polishing, such as a semiconductor substrate, varies among objects to be polished. In the case of an object to be polished having particularly high water repellency, it is difficult for a water-containing cleaning agent to contact the surface of such an object to be polished after polishing. As a result, foreign bodies are unlikely to be removed from the surface of the object to be polished after polishing, resulting in a decrease in the cleaning effect.

Meanwhile, the surface treatment composition of the present invention contains a water-soluble polymer. Thus, due to the effect of the water-soluble polymer, the hydrophilicity (wettability) of the surface of the object to be polished after polishing can be enhanced. As a result, when the object to be polished after polishing is subjected to a surface treatment using the surface treatment composition of the present invention, the removal of foreign bodies from the surface of the object to be polished after polishing can be promoted, and also the drying of deposited foreign bodies, resulting in firm fixation to the surface of the object to be polished after polishing, is suppressed. Therefore, according to the surface treatment composition of the present invention, an excellent foreign body removing effect is obtained.

In addition, the surface treatment composition of the present invention also contains a specific anionic surfactant. At the time of the removal of foreign bodies, the anionic surfactant assists the above water-soluble polymer and particularly promotes the removal of organic residues. As a result, the foreign body removing effect is further enhanced.

The anionic surfactant according to the present invention is capable of forming micelles because of the affinity between moieties other than the anionic group and foreign bodies (particularly hydrophobic components). Thus, presumably, as a result of the dissolution or dispersion of such micelles in the surface treatment composition, foreign bodies, which are hydrophobic components, are effectively removed.

Further, the anionic surfactant according to the present invention contains a specific anionic group (a sulfonic acid (salt) group, a sulfuric acid ester (salt) group, a phosphonic acid (salt) group, a phosphoric acid (salt) group, or a phosphinic acid (salt) group). In the case where the surface of the object to be polished after polishing is cationic, the above specific anionic group is anionized, whereby the anionic surfactant is likely to be adsorbed on the surface of the object to be polished after polishing. As a result, presumably, the surface of the object to be polished after polishing is covered with the anionic surfactant. Meanwhile, on remaining foreign bodies (particularly those likely to be cationic), the anionic group of the anionic surfactant is likely to be adsorbed, whereby the surface of foreign bodies becomes anionic. Thus, the foreign bodies having an anionic surface and the anionized anionic group of the anionic surfactant adsorbed on the surface of the object to be polished after polishing electrostatically repel each other. In addition, in the case where foreign bodies are anionic, the foreign bodies themselves and the anionized anionic group present on the object to be polished after polishing electrostatically repel each other. Therefore, presumably, by utilizing such electrostatic repulsion, foreign bodies can be effectively removed.

Further, supposedly, in the case where the object to be polished after polishing is unlikely to be electrically charged, the mechanism of the removal of foreign bodies is different from the above. First, presumably, foreign bodies (particularly hydrophobic components) are prone to deposition on the object to be polished after polishing, which is hydrophobic, due to a hydrophobic interaction. Here, moieties other than the anionic group (hydrophobic structural moieties) of the anionic surfactant face toward the surface side of the object to be polished after polishing due to their hydrophobicity, while the anionic group, which is a hydrophilic structural moiety, faces toward the opposite side from the surface side of the object to be polished after polishing. Accordingly, supposedly, the surface of the object to be polished after polishing is covered with the anionized anionic group and becomes hydrophilic. As a result, presumably, a hydrophobic interaction is unlikely to occur between foreign bodies (particularly hydrophobic components) and the object to be polished after polishing, whereby the deposition of foreign bodies is further suppressed. Thus, when the surface treatment composition contains an anionic surfactant together with the above water-soluble polymer, the foreign body removing effect is extremely improved.

Further, the water-soluble polymer and the anionic surfactant adsorbed on the surface of the object to be polished after polishing are easily removed by further cleaning with water, for example.

Like this, by using the surface treatment composition of the present invention, foreign bodies present on the surface of an object to be polished after polishing can be effectively removed. Thus, according to the present invention, a surface treatment composition capable of efficiently removing foreign bodies, such as particles and organic residues, remaining on the surface of an object to be polished after polishing is provided. Incidentally, the above mechanisms are based on supposition, and whether they are right or wrong does not affect the technical scope of the present invention.

The present invention will be described hereinafter. Incidentally, the present invention is not limited only to the following embodiments. In addition, as used herein, unless otherwise noted, the operations, physical properties, and the like were measured under conditions of room temperature (20 to 25° C.)/relative humidity of 40 to 50% RH.

### <Surface Treatment Composition>

Hereinafter, each component contained in the surface treatment composition will be described.

### [Water-Soluble Polymer]

The surface treatment composition according to the present invention contains at least one water-soluble polymer selected from the group consisting of water-soluble polysaccharides, polyvinyl alcohols (PVOH) and derivatives thereof, and polyvinylpyrrolidones (PVP) and derivatives thereof. These water-soluble polymers may be used alone, and it is also possible to use a mixture of two or more kinds. Here, the above water-soluble polymers do not include compounds included in the Group B (anionic surfactants) described below in detail. For example, a sulfonic acid group-containing polyvinyl alcohol has a sulfonic acid group and acts as an anionic surfactant; thus, such a polyvinyl alcohol is an anionic surfactant included in Group B and does not belong to the water-soluble polymers included in Group A.

In addition, as used herein, “water-soluble” means that the solubility in water (25° C.) is 1 g/100 mL or more, and “polymer” refers to a polymer having a weight average molecular weight of 1,000 or more. Incidentally, as used herein, a weight average molecular weight can be measured by gel permeation chromatography (GPC), and is specifically measured by the method described in the Examples.

A water-soluble polymer improves the hydrophilicity (wettability) of the surface of an object to be polished after polishing, and thereby suppresses the deposition of foreign bodies to the surface of the object to be polished after polishing to improve the cleaning effect. In addition, the drying of deposited foreign bodies, resulting in firm fixation to the surface of the object to be polished after polishing, is suppressed.

### (Content)

The content of the water-soluble polymer is not particularly limited, but is preferably within the following range.

That is, in the case where a water-soluble polysaccharide is contained as a water-soluble polymer, the content of the water-soluble polysaccharide (in the case where two or more kinds are contained, the total amount; the same hereinafter) is preferably 0.0001 mass % or more based on the total mass of the surface treatment composition. When the content is 0.0001 mass % or more, the foreign body removing effect is improved. From the same point of view, the above content is more preferably 0.001 mass % or more, still more preferably 0.01 mass % or more, and particularly preferably 0.015 mass % or more based on the total mass of the surface treatment composition.

In addition, it is preferable that the content of the water-soluble polysaccharide is 5 mass % or less based on the total mass of the surface treatment composition. When the content is 5 mass % or less, it becomes easy to remove the water-soluble polysaccharide itself after the surface treatment. From the same point of view, the above content is more preferably 3 mass % or less, still more preferably 1 mass % or less, and particularly preferably 0.5 mass % or less based on the total mass of the surface treatment composition.

In the case where a polyvinyl alcohol or a derivative thereof is contained as a water-soluble polymer, the content of the polyvinyl alcohol or derivative thereof (in the case where two or more kinds are contained, the total amount; the same hereinafter) is preferably 0.1 mass % or more based on the total mass of the surface treatment composition. When the content is 0.1 mass % or more, the foreign body removing effect is improved. From the same point of view, the above content is preferably 0.15 mass % or more, particularly preferably 0.3 mass % or more, based on the total mass of the surface treatment composition.

In addition, it is preferable that the content of the polyvinyl alcohol or derivative thereof is 5 mass % or less based on the total mass of the surface treatment composition. When the content is 5 mass % or less, it becomes easy to remove the water-soluble polymer itself after the surface treatment. From the same point of view, the above content is more preferably 3 mass % or less, particularly preferably 1 mass % or less, based on the total mass of the surface treatment composition.

In the case where a polyvinylpyrrolidone or a derivative thereof is contained as a water-soluble polymer, the content of the polyvinylpyrrolidone or derivative thereof (in the case where two or more kinds are contained, the total amount; the same hereinafter) is preferably 0.1 mass % or more based on the total mass of the surface treatment composition. When the content is 0.1 mass % or more, the foreign body removing effect is improved. From the same point of view, the above content is preferably 0.15 mass % or more, particularly preferably 0.3 mass % or more, based on the total mass of the surface treatment composition.

In addition, it is preferable that the content of the polyvinylpyrrolidone or derivative thereof is 5 mass % or less based on the total mass of the surface treatment composition. When the content is 5 mass % or less, it becomes easy to remove the water-soluble polymer itself after the surface treatment. From the same point of view, the above content is more preferably 3 mass % or less, particularly preferably 1 mass % or less, based on the total mass of the surface treatment composition.

Incidentally, in the case where two or more water-soluble polymers selected from the group consisting of water-soluble polysaccharides, polyvinyl alcohols and derivatives thereof, and polyvinylpyrrolidones and derivatives thereof are contained (e.g., in the case where a water-soluble polysaccharide and a polyvinyl alcohol are contained), it is preferable that the content of each water-soluble polymer is within the above content range.

In addition, the mass ratio of the water-soluble polymer selected from Group A to the anionic surfactant selected from Group B (the total mass of water-soluble polymers selected from Group A/the total mass of anionic surfactants selected from Group B) is not particularly limited, but is preferably 0.01 or more. When the mass ratio is 0.01 or more, the foreign body removing effect can be sufficiently obtained. Further, in terms of improving the foreign body removing effect, the above mass ratio is more preferably 0.02 or more, still more preferably 0.10 or more, particularly preferably 0.70 or more, and most preferably 0.80 or more.

Meanwhile, the upper limit of the above mass ratio (the total mass of water-soluble polymers selected from Group A/the total mass of anionic surfactants selected from Group B) is not particularly limited. However, considering the ease of removal of the water-soluble polymer itself after the surface treatment, the upper limit is preferably 100 or less, more preferably 50 or less, still more preferably 20 or less, still more preferably 10 or less, particularly preferably 5 or less, and most preferably 2 or less.

From above, the mass ratio of the water-soluble polymer to the anionic surfactant is preferably 0.01 or more and 100 or less, more preferably 0.02 or more and 50 or less, still more preferably 0.10 or more and 20 or less, still more preferably 0.70 or more and 10 or less, still more preferably 0.70 or more and 5 or less, particularly preferably 0.70 or more and 2 or less, and most preferably 0.80 or more and 2 or less.

### (Weight Average Molecular Weight)

The weight average molecular weight of the water-soluble polymer is not particularly limited, but is preferably within the following range.

That is, in the case where a water-soluble polysaccharide is contained as a water-soluble polymer, it is preferable that the weight average molecular weight of the water-soluble polysaccharide is 10,000 or more. When the weight average molecular weight is 10,000 or more, the hydrophilicity (wettability) of the surface of the object to be polished after polishing is more likely to be enhanced, and the effect of suppressing the deposition of foreign bodies is more likely to be improved. From the same point of view, the above weight average molecular weight is more preferably 100,000 or more, still more preferably 500,000 or more, and particularly preferably 1,000,000 or more.

Meanwhile, the upper limit of the weight average molecular weight of the water-soluble polysaccharide is not particularly limited, but is preferably 3,000,000 or less. When the weight average molecular weight is 3,000,000 or less, the foreign body removing effect is further enhanced. This is supposedly because the hydrophilic polymer removability after a cleaning step becomes even better. From the same point of view, the above weight average molecular weight is more preferably 2,000,000 or less, and particularly preferably 1,500,000 or less.

In the case where a polyvinyl alcohol or a derivative thereof is contained as a water-soluble polymer, it is preferable that the weight average molecular weight of the polyvinyl alcohol or derivative thereof is 10,000 or more. When the weight average molecular weight is 10,000 or more, the effect of suppressing the deposition of foreign bodies is more likely to be improved. From the same point of view, the above weight average molecular weight is more preferably 50,000 or more, and particularly preferably 100,000 or more.

Meanwhile, the upper limit of the weight average molecular weight of the polyvinyl alcohol or derivative thereof is not particularly limited, but is preferably 1,000,000 or less. When the weight average molecular weight is 1,000,000 or less, the foreign body removing effect is further enhanced. From the same point of view, the above weight average molecular weight is more preferably 800,000 or less, and particularly preferably 500,000 or less.

In the case where a polyvinylpyrrolidone or a derivative thereof is contained as a water-soluble polymer, it is preferable that the weight average molecular weight of the polyvinylpyrrolidone or derivative thereof is 5,000 or more. When the weight average molecular weight is 5,000 or more, the effect of suppressing the deposition of foreign bodies is more likely to be improved. From the same point of view, the above weight average molecular weight is more preferably 15,000 or more, and particularly preferably 30,000 or more.

Meanwhile, the upper limit of the weight average molecular weight of the polyvinylpyrrolidone or derivative thereof is not particularly limited, but is preferably 500,000 or less. When the weight average molecular weight is 500,000 or less, the foreign body removing effect is further enhanced. From the same point of view, the above weight average molecular weight is more preferably 300,000 or less, and particularly preferably 100,000 or less.

Incidentally, the above weight average molecular weight can be measured by gel permeation chromatography (GPC), and is specifically a value measured by the method described in the Examples.

Hereinafter, the kinds of water-soluble polymers included in Group A will be described.

### (Water-Soluble Polysaccharide)

It is preferable that the surface treatment composition according to the present invention contains a water-soluble polysaccharide as a water-soluble polymer. In Group A, water-soluble polysaccharides can enhance the foreign body removing effect in small amounts. Here, “polysaccharide” refers to a saccharide obtained by the polymerization of a large number of monosaccharide molecules through a glycosidic linkage.

Water-soluble polysaccharides are not particularly limited as long as the above definition is satisfied, and examples thereof include polysaccharides such as cellulose derivatives and starch derivatives. In one embodiment of the present invention, it is preferable that the water-soluble polysaccharide as a water-soluble polymer includes at least one member selected from the group consisting of cellulose derivatives and starch derivatives.

A cellulose derivative is a polymer having a n-glucose unit as a main repeating unit. Specific examples of cellulose derivatives include hydroxyethyl cellulose (HEC), hydroxypropyl cellulose, hydroxyethyl methyl cellulose, hydroxypropyl methyl cellulose, methyl cellulose, ethyl cellulose, ethylhydroxyethyl cellulose, carboxymethyl cellulose, and the like. Among them, in terms of availability and also of making it easier to obtain the effects of the present invention, hydroxyethyl cellulose (HEC) is preferable.

A starch derivative is a polymer having an α-glucose unit as a main repeating unit. Specific examples of starch derivatives include pregelatinized starch, pullulan, carboxymethyl starch, cyclodextrin, and the like. Among them, in terms of availability and also of making it easier to obtain the effects of the present invention, pullulan is preferable.

Considering the foreign body removing effect and availability, it is preferable that the water-soluble polysaccharide as a water-soluble polymer is a cellulose derivative.

Incidentally, the above water-soluble polysaccharides may be used alone, and it is also possible to use a combination of two or more kinds. In addition, water-soluble polysaccharides may be commercially available products or synthetic products.

As the commercially available products, for example, hydroxyethyl cellulose (SP series manufactured by Daicel FineChem Ltd., CF series manufactured by Sumitomo Seika Chemicals Co., Ltd.), and the like may be used.

### (Polyvinyl Alcohol and Derivative Thereof)

A polyvinyl alcohol or a derivative thereof for use as the water-soluble polymer according to the present invention is not particularly limited as long as it is a polymer containing a structural unit derived from vinyl alcohol as a main component. Examples thereof include usual polyvinyl alcohols obtained by hydrolyzing polyvinyl acetate; and derivatives of polyvinyl alcohols, such as modified polyvinyl alcohols. In addition, the saponification degree of the polyvinyl alcohol or derivative thereof is not particularly limited. The saponification degree of the polyvinyl alcohol or derivative thereof can be freely selected as long as the water solubility is not impaired, but is preferably 5% or more and 99.5% or less, more preferably 50% or more and 99.5% or less, still more preferably 60% or more and 99.5% or less, particularly preferably 70% or more and 99.5% or less, and most preferably 70% or more and less than 99.5%. Within such a range, the decomposition of the polyvinyl alcohol or derivative thereof is suppressed, and the excellent cleaning effect of the surface treatment composition is likely to be maintained.

Examples of modified vinyl alcohols include polyvinyl alcohols modified with a water-soluble group such as an acetoacetyl group, an acetyl group, an ethylene oxide group, or a carboxyl group; butenediol/vinyl alcohol copolymers, and the like.

These polyvinyl alcohols may be used alone, or it is also possible to use a combination of two or more kinds having different degrees of polymerization or different types of modification, for example. In addition, polyvinyl alcohols may be commercially available products or synthetic products.

As the commercially available products, for example, polyvinyl alcohol (JMR H series, HH series, M series, and L series manufactured by Japan Vam & Poval Co., Ltd., Kuraray Poval (PVA series) manufactured by Kuraray Co., Ltd., and Gosenol series manufactured by Nippon Synthetic Chemical Industry Co., Ltd.), ethylene oxide group-modified polyvinyl alcohol (GOHSENX (registered trademark; the same hereinafter) LW series and WO series manufactured by Nippon Synthetic Chemical Industry Co., Ltd.), acetoacetyl group-modified polyvinyl alcohol (GOHSENX Z series manufactured by Nippon Synthetic Chemical Industry Co., Ltd.), butenediol/vinyl alcohol copolymer (Nichigo G-Polymer series manufactured by Nippon Synthetic Chemical Industry Co., Ltd.), and the like may be used.

### (Polyvinylpyrrolidone and Derivative Thereof)

A polyvinylpyrrolidone or a derivative thereof for use as the water-soluble polymer according to the present invention is not particularly limited as long as it is a polymer containing a structural unit derived from vinylpyrrolidone as a main component. Examples thereof include polyvinylpyrrolidones; and derivatives of polyvinylpyrrolidones, including, for example, polyvinyl alcohol-based graft polymers such as polyvinylpyrrolidone/polyvinyl alcohol copolymers. Incidentally, in the case where a water-soluble polymer has both a polyvinyl alcohol backbone and a polyvinylpyrrolidone backbone, such a water-soluble polymer is included in derivatives of polyvinylpyrrolidones.

These polyvinylpyrrolidones may be used alone, or it is also possible to use a combination of two or more kinds having different degrees of polymerization or different types of modification, for example. In addition, polyvinylpyrrolidones may be commercially available products or synthetic products.

As the commercially available products, for example, polyvinylpyrrolidone (PITZCOL (registered trademark; the same hereinafter) K series manufactured by DKS Co., Ltd., and polyvinylpyrrolidone series manufactured by Nippon Shokubai Co., Ltd.), polyvinylpyrrolidone/polyvinyl alcohol copolymer (PITZCOL V series manufactured by DKS Co., Ltd.), and the like may be used.

### [Anionic Surfactant]

The surface treatment composition according to the present invention contains at least one anionic surfactant selected from the group consisting of compounds having a sulfonic acid (salt) group, compounds having a sulfuric acid ester (salt) group, compounds having a phosphonic acid (salt) group, compounds having a phosphoric acid (salt) group, and compounds having a phosphinic acid (salt) group. These anionic surfactants may be used alone, and it is also possible to use a mixture of two or more kinds. Incidentally, as used herein, “anionic surfactant” refers to a compound having an anionic moiety in the molecule (i.e., a sulfonic acid (salt) group, a sulfuric acid ester (salt) group, a phosphonic acid (salt) group, a phosphoric acid (salt) group, or a phosphinic acid (salt) group) and also having surface activity.

An anionic surfactant assists the foreign body removing effect of the above hydrophilic polymer and contributes to the removal of foreign bodies by the surface treatment composition. Thus, in the surface treatment (cleaning, etc.) of an object to be polished after polishing, the surface treatment composition containing the above anionic surfactant can sufficiently remove foreign bodies (particles or organic residues) remaining on the surface of the object to be polished after polishing.

### (Content)

The content of the anionic surfactant is not particularly limited, but is preferably within the following range.

That is, it is preferable that the content of the anionic surfactant (in the case where two or more kinds are contained, the total amount; the same hereinafter) is 0.001 mass % or more based on the total mass of the surface treatment composition. When the content is 0.001 mass % or more, the foreign body removing effect is further improved. This is supposedly because when the anionic surfactant is adsorbed on (covers) the object to be polished after polishing and foreign bodies, the adsorption (covering) takes place in a larger area. As a result, particularly foreign bodies form micelles more easily, whereby the foreign body removing effect caused by the dissolution/dispersion of the micelles is improved. In addition, supposedly, this is also because as a result of an increase in the number of anionic groups, the electrostatic adsorption or repulsion effect can be developed more strongly. From the same point of view, the above content is preferably 0.005 mass % or more, more preferably 0.01 mass % or more, based on the total mass of the surface treatment composition.

In addition, it is preferable that the content of the anionic surfactant is 3 mass % or less based on the total mass of the surface treatment composition. When the content is 3 mass % or less, the foreign body removing effect is further enhanced. This is supposedly because the removability of the anionic surfactant itself after a cleaning step becomes excellent. From the same point of view, the above content is more preferably 1 mass % or less, still more preferably 0.1 mass % or less, and particularly preferably 0.05 mass % or less based on the total mass of the surface treatment composition.

Hereinafter, the kinds of anionic surfactants included in Group B will be described.

### (Compound Having Sulfonic Acid (Salt) Group)

A compound having a sulfonic acid (salt) group as the anionic surfactant according to the present invention is not particularly limited as long as it is a surfactant having a sulfonic acid (salt) group. Incidentally, as used herein, “sulfonic acid (salt) group” refers to a sulfonic acid group (—SO₂(OH)) or a salt thereof. Incidentally, as used herein, “having a sulfonic acid (salt) group” means that the compound has a sulfonic acid group (—SO₂(OH)) or a partial structure expressed as a salt thereof (—SO₂ (OM¹); here, M¹ is an organic or inorganic cation).

Examples of compounds having a sulfonic acid (salt) group include low molecular weight surfactants, such as sulfonic acid salts including n-dodecylbenzene sulfonic acid, ammonium lauryl sulfonate, sodium alkyl diphenyl ether disulfonate, polyoxyalkylene alkyl ether sulfonic acid, polyoxyalkylene allyl ether sulfonic acid, polyoxyalkylene alkyl phenyl ether sulfonic acid, polyoxyalkylene polycyclic phenyl ether sulfonic acid, and polyoxyalkylene allyl phenyl ether sulfonic acid, and the like, as well as high molecular weight surfactants. These compounds may be used alone, and it is also possible to use a combination of two or more kinds. Incidentally, as used herein, “low molecular weight surfactant” refers to a compound having a molecular weight of less than 1,000. Incidentally, the molecular weight of a compound can be performed, for example, using a known mass spectrometry technique such as TOF-MS or LC-MS. Meanwhile, as used herein, “high molecular weight surfactant” refers to a compound having a molecular weight (weight average molecular weight) of 1,000 or more. The weight average molecular weight can be measured by gel permeation chromatography (GPC), and is specifically measured by the method described in the Examples.

In terms of improving the foreign body removing effect, it is preferable to use a high molecular weight surfactant as a compound having a sulfonic acid (salt) group. Examples of high molecular weight surfactants having a sulfonic acid (salt) group (as used herein, also referred to as “sulfonic acid group-containing polymer) include, for example, polymer compounds obtained by sulfonating the base polymer compounds and polymer compounds obtained by (co)polymerizing a monomer having a sulfonic acid (salt) group.

More specific examples include sulfonic acid (salt) group-containing polystyrenes such as sodium polystyrene sulfonate and ammonium polystyrene sulfonate, sulfonic acid (salt) group-containing polyvinyl alcohols (sulfonic acid-modified polyvinyl alcohols), sulfonic acid (salt) group-containing polyvinyl acetates (sulfonic acid-modified polyvinyl acetates), sulfonic acid (salt) group-containing polyesters, copolymers of styrene/sulfonic acid (salt) group-containing monomer, copolymers of (meth)acrylic acid/sulfonic acid (salt) group-containing monomer, and copolymers of maleic acid/sulfonic acid (salt) group-containing monomer. Incidentally, as used herein, in the specific names of compounds, the indication “(meth)acrylic” refers to “acrylic” and “methacrylic”, and “(meth)acrylate” refers to “acrylate” and “methacrylate.”

In these polymers, at least part of the sulfonic acid group may be in the form of a salt. Examples of salts include alkali metal salts such as sodium salts, salts of Group II elements such as calcium salts, amine salts, ammonium salts, and the like. In particular, in the case where the object to be polished after polishing is a semiconductor substrate after a CMP step, in terms of removing metals on the substrate surface as much as possible, an amine salt or an ammonium salt is preferable.

Among the above examples, for the high effect of improving the foreign body removability, it is preferable that the anionic surfactant includes at least one member selected from the group consisting of polystyrene sulfonic acids (sulfonic acid group-containing polystyrenes), salts thereof, and sulfonic acid (salt) group-containing polyvinyl alcohols (sulfonic acid-modified polyvinyl alcohols). That is, it is preferable that the anionic surfactant selected from the Group B includes at least one member selected from the group consisting of sulfonic acid (salt) group-containing polystyrenes and sulfonic acid (salt) group-containing polyvinyl alcohols. In these anionic surfactants, structurally, the density of sulfonic acid (salt) groups is relatively high. Accordingly, electrostatic repulsion force is likely to be obtained, and, as a result, the foreign body removing effect is further improved. From the same point of view, it is more preferable that the anionic surfactant includes a polystyrene sulfonic acid (sulfonic acid group-containing polystyrene) or a salt thereof.

In the present invention, it is preferable that the sulfonic acid group-containing polymer has a weight average molecular weight of 1,000 or more. When the weight average molecular weight is 1,000 or more, the foreign body removing effect is further enhanced. This is supposedly because the adsorptivity (covering properties) at the time of covering the object to be polished after polishing or foreign bodies is further improved, resulting in further improvement in the action of removing foreign bodies from the surface of the object to be polished after polishing or the action of suppressing the re-deposition of organic residues to the surface of the object to be polished after polishing. From the same point of view, the weight average molecular weight is more preferably 8,000 or more, still more preferably 15,000 or more, and particularly preferably 50,000 or more.

In addition, it is preferable that the weight average molecular weight of the sulfonic acid group-containing polymer is 3,000,000 or less. When the weight average molecular weight is 3,000,000 or less, the foreign body removing effect is further enhanced. This is supposedly because the removability of the sulfonic acid group-containing polymer after a cleaning step becomes even better. From the same point of view, the weight average molecular weight is more preferably 2,000,000 or less, still more preferably 1,000,000 or less, and particularly preferably 100,000 or less.

The above sulfonic acid group-containing polymers may be used alone, and it is also possible to use a combination of two or more kinds. In addition, sulfonic acid group-containing polymers may be commercially available products or synthetic products.

As the commercially available products, for example, sulfonic acid-modified polyvinyl alcohol (GOHSENX L series manufactured by Nippon Synthetic Chemical Industry Co., Ltd.), sulfonic acid group-containing copolymer (ARON (registered trademark) A series manufactured by Toagosei Co., Ltd.), sulfonic acid group-containing copolymer (VERSA (registered trademark; the same hereinafter) series and NARLEX (registered trademark; the same hereinafter) series manufactured by Akzo Nobel; ST series and MA series manufactured by Tosoh Organic Chemical Co., Ltd.), polystyrene sulfonic acid (salt) (PolyNaSS (registered trademark; the same hereinafter) series manufactured by Tosoh Organic Chemical Co., Ltd.), polyoxyalkylene allyl phenyl ether sulfuric acid (salt) (New Kargen (registered trademark; the same hereinafter) FS-7S manufactured by Takemoto Oil & Fat Co., Ltd.), alkyl diphenyl ether disulfonic acid salt (PIONIN A-43-D and TAKESURF A-43-NQ manufactured by Takemoto Oil & Fat Co., Ltd.), and the like may be used.

### (Compound Having Sulfuric Acid Ester (Salt) Group)

A compound having a sulfuric acid ester (salt) group as the anionic surfactant according to the present invention is not particularly limited as long as it is a surfactant having a sulfuric acid ester (salt) group. Incidentally, as used herein, “sulfuric acid ester (salt) group” refers to a sulfuric acid ester group (—OSO₂(OH)) or a salt thereof. Incidentally, as used herein, “having a sulfuric acid ester (salt) group” means that the compound has a sulfuric acid ester group (—OSO₂(OH)) or a partial structure expressed as a salt thereof (—OSO₂ (OM²); here, M² is an organic or inorganic cation).

Examples of compounds having a sulfuric acid ester (salt) group include alkyl sulfuric acid ester salts, polyoxyethylene alkyl ether sulfuric acid ester salts, polyoxyethylene alkyl allyl phenyl ether sulfuric acid ester salts, polyoxyalkylene allyl ether sulfuric acid ester salts, polyoxyethylene alkyl phenyl ether sulfuric acid ester salts, polyoxyethylene polycyclic phenyl ether sulfuric acid ester salts, and the like. These compounds may be used alone, and it is also possible to use a combination of two or more kinds. Incidentally, examples of salts are the same as those described above in (Compound having Sulfonic Acid (Salt) Group).

Compounds having a sulfuric acid ester (salt) group may be commercially available products or synthetic products. As the commercially available products, for example, polyoxyethylene alkyl allyl phenyl ether sulfuric acid ester salt (AQUALON (registered trademark; the same hereinafter) HS-10 manufactured by DKS Co., Ltd.), polyoxyethylene alkyl ether sulfuric acid ester salt (Newcol (registered trademark; the same hereinafter) 1020-SN manufactured by Nippon Nyukazai Co., Ltd.), polyoxyethylene polycyclic phenyl ether sulfuric acid ester salt (Newcol 707 series manufactured by Nippon Nyukazai Co., Ltd.), polyoxyethylene allyl ether sulfuric acid ester salt (Newcol B4-SN manufactured by Nippon Nyukazai Co., Ltd.), and the like can be mentioned.

### (Compound Having Phosphonic Acid (Salt) Group)

A compound having a phosphonic acid (salt) group as the anionic surfactant according to the present invention is not particularly limited as long as it is a surfactant having a phosphonic acid (salt) group. Incidentally, as used herein, “phosphonic acid (salt) group” refers to a phosphonic acid group (—PO(OH)₂) or a salt thereof. Incidentally, as used herein, “having a phosphonic acid (salt) group” means that the compound has a phosphonic acid group (—PO(OH)₂) or a partial structure expressed as a salt thereof (—PO(OM³)₂ or —PO(OH)(OM³); here, M³ is an organic or inorganic cation).

As compounds having a phosphonic acid (salt) group, for example, known compounds, such as dodecylphosphonic acid, may be used. These compounds may be used alone, and it is also possible to use a combination of two or more kinds. Incidentally, examples of salts are the same as those described above in (Compound having Sulfonic Acid (Salt) Group).

### (Compound Having Phosphoric Acid (Salt) Group)

A compound having a phosphoric acid (salt) group as the anionic surfactant according to the present invention is not particularly limited as long as it is a surfactant having a phosphoric acid (salt) group. Incidentally, as used herein, “phosphoric acid (salt) group” refers to a phosphoric acid group (—OPO(OH)₂) or a salt thereof. Incidentally, as used herein, “having a phosphoric acid (salt) group” means that the compound has a phosphoric acid group (—OPO(OH)₂) or a partial structure expressed as a salt thereof (—OPO(OM⁴)₂ or —OPO(OH)(OM⁴); here, M⁴ is an organic or inorganic cation).

Examples of compounds having a phosphoric acid (salt) group include monoalkyl phosphoric acids, alkyl ether phosphoric acids, polyoxyethylene alkyl ether phosphoric acids, polyoxyethylene allyl phenyl ether phosphoric acids, polyoxyethylene alkyl phenyl ether phosphoric acids, and the like. These compounds may be used alone, and it is also possible to use a combination of two or more kinds. Incidentally, examples of salts are the same as those described above in (Compound having Sulfonic Acid (Salt) Group).

Compounds having a phosphoric acid (salt) group may be commercially available products or synthetic products. As the commercially available products, for example, polyoxyethylene alkyl ether phosphoric acid (NIKKOL (registered trademark; the same hereinafter) DLP, DOP, DDP, TLP, TCP, TOP, and TDP series manufactured by Nikko Chemicals Co., Ltd.) and polyoxyethylene allyl phenyl ether phosphoric acid salt (phosphoric acid ester (phosphate) series (New Kargen FS-3AQ, New Kargen FS-3PG, etc.) manufactured by Takemoto Oil & Fat Co., Ltd.) can be mentioned.

### (Compound Having Phosphinic Acid (Salt) Group)

A compound having a phosphinic acid (salt) group as the anionic surfactant according to the present invention is not particularly limited as long as it is a surfactant having a phosphinic acid (salt) group. Incidentally, as used herein, “phosphinic acid (salt) group” refers to a phosphinic acid group (—P(═O)(OH)— or —P(═O)(H)(OH)) or a salt thereof. Incidentally, as used herein, “having a phosphinic acid (salt) group” means that the compound has a phosphinic acid group (—P(═O)(OH)— or —P(═O)(H)(OH)) or a partial structure expressed as a salt thereof (—P(═O)(OM⁵)- or —P(═O)(H)(OM⁵); here, M⁵ is an organic or inorganic cation).

Examples of compounds having a phosphinic acid (salt) group include monoalkyl phosphinic acids, dialkyl phosphinic acids, bis(poly-2-carboxyethyl) phosphinic acid, bis-poly(1,2-dicarboxyethyl) phosphinic acid, bis-poly[2-carboxy-(2-carboxymethyl)ethyl] phosphinic acid, phosphino polycarboxylic acid copolymers, and the like. These compounds may be used alone, and it is also possible to use a combination of two or more kinds. Incidentally, examples of salts are the same as those described above in (Compound having Sulfonic Acid (Salt) Group).

Compounds having a phosphinic acid (salt) group may be commercially available products or synthetic products. As the commercially available products, for example, bis(poly-2-carboxyethyl) phosphinic acid (Belsperse (registered trademark; the same hereinafter) 164 manufactured by BWA), phosphino polycarboxylic acid copolymer (Belclene (registered trademark; the same hereinafter) 400 manufactured by BWA), and the like can be mentioned.

### [Preferred Modes of Compounds of Group A and Group B]

The surface treatment composition according to the present invention contains one or more water-soluble polymer selected from the above Group A and one or more anionic surfactant selected from the above Group B. At this time, the combination of a water-soluble polymer and an anionic surfactant is preferably a combination of at least one member selected from water-soluble polysaccharides, polyvinylpyrrolidones, and derivatives thereof and a compound having a sulfonic acid (salt) group, and particularly preferably a combination of a water-soluble polysaccharide and a compound having a sulfonic acid (salt) group. When a water-soluble polymer and an anionic surfactant are contained in the above combination, the foreign body removing effect is further improved.

### [Dispersion Medium]

The surface treatment composition according to the present invention contains water as a dispersion medium (solvent). A dispersion medium functions to disperse or dissolve each component. It is more preferable that the dispersion medium is composed only of water. In addition, for the dispersion or dissolution of each component, the dispersion medium may also be a mixed solvent of water and an organic solvent. Examples of organic solvents used in this case include water-miscible organic solvents such as acetone, acetonitrile, ethanol, methanol, isopropanol, glycerin, ethylene glycol, and propylene glycol. In addition, it is also possible that these organic solvents are used without mixing with water, and mixed with water after dispersing or dissolving each component. These organic solvents may be used alone, and it is also possible to use a combination of two or more kinds.

As water, in terms of inhibiting the contamination of the object to be polished after polishing (object to be cleaned) and the action of other components, water containing as little impurities as possible is preferable. For example, water in which the total content of transition metal ions is 100 mass ppb or less is preferable. Here, the purity of water can be enhanced, for example, by removal of impurity ions using an ion exchange resin, removal of foreign bodies through a filter, distillation, or like operations. Specifically, as water, it is preferable to use deionized water (ion exchange water), pure water, ultrapure water, distilled water, or the like, for example.

[pH]

The pH of the surface treatment composition according to the present invention is not particularly limited, but is preferably 4 or more and 12 or less. When the pH is 4 or more, the electrostatic repulsion of the anionic surfactant can be obtained more effectively, whereby the foreign body removing effect is improved. In addition, from the same point of view, the pH is more preferably 5 or more, still more preferably 6 or more, particularly preferably 7 or more, and most preferably more than 7.

Meanwhile, the pH is preferably 12 or less. A pH of 12 or less is preferable in terms of the ease of handling at the time of using the surface treatment composition or at the time of treating the composition after use. In addition, from the same point of view, the pH is more preferably 11 or less.

Incidentally, the pH of the surface treatment composition can be checked using a pH meter (manufactured by HORIBA, Ltd., product name: LAQUA (registered trademark; the same hereinafter)).

Further, without interfering with the effects of the present invention, the surface treatment composition according to the present invention may further contain a pH adjuster and a pH buffer for the purpose of adjusting the pH within the above preferred ranges.

### (pH Adjuster)

The surface treatment composition according to the present invention may further contain a pH adjuster. A pH adjuster adjusts the pH of the surface treatment composition to a suitable value. As a result, the foreign body removability can be improved.

Known acids, bases, and salts thereof may be used as pH adjusters. Specific examples of acids usable as pH adjusters include inorganic acids such as hydrochloric acid, sulfuric acid, nitric acid, fluoric acid, boric acid, carbonic acid, hypophosphorous acid, phosphorous acid, and phosphoric acid, and organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenyl acetic acid, and phenoxyacetic acid. Among these, it is preferable that the pH adjuster is a polycarboxylic acid such as succinic acid, maleic acid, citric acid, tartaric acid, malic acid, or itaconic acid, or a salt thereof. Such an acid can be coordinated to foreign bodies (particles, etc.) through a plurality of carbonyl groups. As a result, due to the chelating effect, foreign bodies are dispersed in the surface treatment composition more easily, whereby the removing effect is further improved.

Examples of bases usable as pH adjusters include amines such as aliphatic amines and aromatic amines, including ethanolamine, 2-amino-2-ethyl-1,3-propanediol, and the like, organic bases such as quaternary ammonium hydroxide, hydroxides of alkali metals such as potassium hydroxide, hydroxides of alkaline earth metals, tetramethyl ammonium hydroxide, ammonia, and the like.

The above pH adjusters may be used alone, and it is also possible to use a mixture of two or more kinds.

In addition, in place of the above acids or in combination with the above acids, salts of alkali metal salts of the above acids, such as ammonium salts, sodium salts, and potassium salts, may also be used as pH adjusters. In particular, in the case where a combination of a weak acid and a strong base, a strong acid and a weak base, or a weak acid and a weak base is used, the pH buffering action can be expected. In such a case, the pH adjuster can serve also as a pH buffer. That is, a surface treatment composition containing a pH adjuster having the pH buffering action corresponds to a surface treatment composition containing a pH buffer.

Among them, considering handleability in the preparation of a surface treatment composition, a combination of a weak acid and a weak base is preferable. Examples of such combinations include a combination of a weak acid selected from polycarboxylic acids such as succinic acid, maleic acid, and citric acid and a weak base selected from ammonia and amines such as aliphatic amines, aromatic amines, and the like.

The amount of pH adjuster added is not particularly limited, and should be a suitable amount such that the polishing composition has a desired pH.

### (pH Buffer)

It is preferable that the surface treatment composition according to the present invention further contains a pH buffer. A pH buffer maintains the pH of the surface treatment composition constant, thereby suppressing changes in the pH of the surface treatment composition at the time of performing a surface treatment (preferably rinse polishing). As a result, the object to be polished after polishing can be surface-treated while maintaining the preferred pH without a decrease in the foreign body removability.

pH buffers are not particularly limited as long as they are capable of suppressing changes in pH within the desired pH range. Examples of pH buffers suitable for use in the present invention include a combination of a weak acid and a conjugate base, a combination of a weak base and a conjugate acid, and a compound having acidic and basic structures in one molecule and functioning as a buffer. They will be described hereinafter.

### <<Combination of Weak Acid and Conjugate Base>>

Weak acids and conjugate bases are not particularly limited, and examples thereof are as follows.

Examples of weak acids include amino group-containing compounds that serve as weak acids (taurine, aspartic acid, iminodiacetic acid, ethylenediaminetetraacetic acid (EDTA), nitrilotriacetic acid (NTA), hydroxyethyl ethylenediaminetetraacetic acid, hydroxyethyl iminodiacetic acid, dihydroxyethyl glycine, 1,3-propanediaminetetraacetic acid, 1,3-diamino-2-hydroxypropanetetraacetic acid, N-tris(hydroxymethyl)methyl-2-aminoethanesulfonic acid, etc.); carboxylic acids (citric acid, formic acid, gluconic acid, lactic acid, oxalic acid, tartaric acid, phthalic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, itaconic acid, maleic acid, adipic acid, pimelic acid, succinic acid, glutaric acid, malic acid, malonic acid, phthalic acid, salicylic acid, glyceric acid, oxalic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenyl acetic acid, phenoxyacetic acid, etc.); inorganic acids (phosphoric acid, hypophosphorous acid, phosphorous acid, boric acid, etc.); phosphonic acids (diethylenetriamine pentamethylene phosphonic acid, aminotrimethylene phosphonic acid, 2-phosphonobutane-1,2,4-tricarboxylic acid, 1-hydroxyethylidene-1,1,diphosphonic acid, etc.); organic sulfonic acids (isethionic acid, etc.); carbonic acid, and the like.

A conjugate base should be a conjugate base of the used weak acid. Examples thereof include hydroxides of alkali metals, such as lithium hydroxide, sodium hydroxide, and potassium hydroxide; other alkali metal salts such as potassium salts, sodium salts, and lithium salts; ammonium salts; amine salts; and compounds corresponding to the weak bases described below in <<Combination of Weak Base and Conjugate Acid>>. In addition, depending on the kind of weak acid selected from the above, a weak acid having higher pKa than the selected weak acid also serves as a conjugate base and thus may be used as a conjugate base.

### <<Combination of Weak Base and Conjugate Acid>>

Weak bases and conjugate acids are not particularly limited, and examples thereof are as follows.

Examples of weak bases include aminoalcohols (diethylethanolamine, diethanolamine, triethanolamine, trishydroxymethyl aminomethane, D-glucamine, N-methyl-D-glucamine, acetylglucosamine, ethanolamine, 2-amino-2-ethyl-1,3-propanediol, isopropanolamine, diisopropanolamine, tri-isopropanolamine, diglycolamine, etc.); amine compounds such as aliphatic amines (aliphatic primary amines such as methylamine, ethylamine, propylamine, n-butylamine, sec-butylamine, tert-butylamine, and cyclohexylamine, aliphatic secondary amines such as dimethylamine, diethylamine, dipropylamine, dibutylamine, diisobutylamine, di-sec-butylamine, and di-tert-butylamine, aliphatic tertiary amines such as trimethylamine, triethylamine, tripropylamine, and tributylamine, etc.), aromatic amines (benzylamine, aniline, diphenylamine, etc.), and cyclic amines (pyridine, piperazine, etc.); and ammonium compounds (quaternary ammonium compounds such as tetramethyl ammonium hydroxide, tetraethyl ammonium hydroxide, tetrapropyl ammonium hydroxide, ammonium hydroxide, etc.).

Examples of conjugate acids include hydrochloric acid; sulfuric acid; nitric acid; phosphoric acid; carboxylic acid; and compounds or the like corresponding to the weak acids described above in <<Combination of Weak Acid and Conjugate Base>>. In addition, depending on the kind of weak base selected from the above, a weak base having smaller pKa than the selected weak base also serves as a conjugate acid and thus may be used as a conjugate acid.

### <<Compound Having Acidic and Basic Structures in One Molecule and Functioning as Buffer>>

Compounds having acidic and basic structures in one molecule and functioning as buffers are not particularly limited, and examples thereof are as follows. Examples of such compounds include amino acids whose function as an acid is weak (hydroxyproline, threonine, serine, glycine, glycylglycine, α-aminobutyric acid, β-aminobutyric acid, valine, cysteine, methionine, isoleucine, leucine, tyrosine, phenylalanine, beta-alanine, etc.); and other amino group-containing compounds whose function as an acid is weak (trishydroxymethyl aminomethane, 1,3-bis[tris(hydroxymethyl)methylamino]propane, etc.).

The above pH buffers may be used alone, and it is also possible to use a combination of two or more kinds.

Among them, considering pH buffering properties, availability, foreign body removability, and the like, it is preferable that the pH buffer includes at least one member selected from the group consisting of phosphoric acid, succinic acid, tartaric acid, itaconic acid, citric acid, maleic acid, malic acid, and iminodiacetic acid, as well as potassium salts, ammonium salts, and amine salts thereof; and trishydroxymethyl aminomethane, 2-amino-2-ethyl-1,3-propanediol, and diglycolamine, as well as phosphoric acid salts and carboxylic acid salts thereof.

In addition, in terms of further improving the foreign body removability, it is preferable that the pH buffer includes at least one member selected from the group consisting of citric acid, maleic acid, malic acid, and iminodiacetic acid, as well as ammonium salts and amine salts thereof; trishydroxymethyl aminomethane, 2-amino-2-ethyl-1,3-propanediol, and diglycolamine, as well as carboxylic acid salts thereof. Further, in terms of improving the foreign body removability, it is preferable that the pH buffer includes a polycarboxylic acid or a salt thereof. Such an acid or a salt thereof can be coordinated to foreign bodies (particles, etc.) through a plurality of carbonyl groups. As a result, due to the chelating effect, foreign bodies are dispersed in the surface treatment composition more easily, whereby the removing effect is further improved. Further, in terms of improving the foreign body removability, it is preferable that the pH buffer includes at least one member selected from the group consisting of citric acid, maleic acid, malic acid, and iminodiacetic acid, as well as ammonium salts and amine salts thereof. Further, from the same point of view, it is preferable that the pH buffer includes diammonium hydrogen citrate or iminodiacetic acid.

The content of the pH buffer (in the case where two or more kinds are contained, the total amount; the same hereinafter) is not particularly limited, but is preferably 0.01 mass % or more based on the total mass of the surface treatment composition. When the content of the pH buffer is 0.01 mass % or more, the foreign body removing effect is further improved. This is supposedly because the pH of the surface treatment composition can be maintained constant more easily, which prevents a decrease in the foreign body removing effect. From the same point of view, it is more preferable that the content of the pH buffer is 0.02 mass % or more based on the total mass of the surface treatment composition. In addition, it is preferable that the content of the pH buffer is 5 mass % or less based on the total mass of the surface treatment composition. A pH buffer content of 5 mass % or less is preferable in terms of cost reduction. From the same point of view, the content of the pH buffer is more preferably 3 mass % or less, still more preferably 1 mass % or less, and particularly preferably less than 1 mass % based on the total mass of the surface treatment composition.

### [Other Additives]

Without interfering with the effects of the present invention, the surface treatment composition according to the present invention may further contain other additives in any proportions as necessary. However, components other than the essential components of the surface treatment composition according to the present invention may cause foreign bodies, and thus the addition is desirably minimized. Thus, it is preferable that components other than the essential components are added in as small amounts as possible, and it is more preferable that no such components are contained. Examples of other additives include abrasive grains, antiseptic agents, dissolved gases, reducing agents, oxidizing agents, and the like. Among them, for further improving the foreign body removing effect, it is preferable the surface treatment composition contains substantially no abrasive grains. Here, “to contain substantially no abrasive grains” refers to the case where the content of abrasive grains based on the whole surface treatment composition is 0.01 mass % or less.

### <Method for Producing Surface Treatment Composition>

The method for producing the above surface treatment composition is not particularly limited. For example, the surface treatment composition can be prepared by mixing at least one water-soluble polymer selected from the above Group A, at least one anionic surfactant selected from the above Group B, and water. That is, according to another mode of the present invention, a method for producing the above surface treatment composition, including mixing at least one water-soluble polymer selected from the above Group A, at least one anionic surfactant selected from the above Group B, and water, is also provided. The kinds, added amounts, and the like of the water-soluble polymer and the anionic surfactant are as described above. Further, in the method for producing a surface treatment composition according to one mode of the present invention, a pH adjuster, a pH buffer, other additives, and a dispersion media except for water may be added as necessary. The kinds, added amounts, and the like thereof are as described above.

The order of the addition of the above components and the addition methods are not particularly limited. The above materials may be added at once or separately, in stages or continuously. In addition, the mixing method is not particularly limited either, and a known method may be used. Preferably, the method for producing a surface treatment composition includes sequentially adding at least one water-soluble polymer selected from the above Group A and at least one anionic surfactant selected from the above Group B, optionally together with a pH adjuster, a pH buffer, and other additives, and stirring them in water. In addition, the method for producing a surface treatment composition may include measuring the pH of the surface treatment composition and adjusting the pH to 4 or more and 12 or less.

<Object to be Polished after Polishing>

The surface treatment composition according to one mode of the present invention is capable of effectively removing foreign bodies remaining on the surface of various objects to be polished after polishing. At this time, the object to be polished (preferably “object to be rinse polished”) after polishing is not particularly limited. Incidentally, as used herein, an object to be polished after polishing means an object to be polished that has been polished in a polishing step. The polishing step is not particularly limited, but is preferably a CMP step.

The object to be polished after polishing is preferably a polished semiconductor substrate, and more preferably a semiconductor substrate after CMP. The reason therefor is as follows: because particularly organic residues may cause the breakage of a semiconductor device, in the step of cleaning a semiconductor substrate, foreign bodies containing organic residues need to be removed as much as possible.

Among them, the surface treatment composition is suitable for use in the rinse polishing of a silicon-containing material. In particular, the surface treatment composition according to the present invention can effectively reduce foreign bodies remaining on the surface of an object to be polished after polishing containing silicon nitride, silicon oxide, or polysilicon.

Here, in terms of the effects caused by the present invention, it is preferable that the surface treatment composition according to the present invention is used for reducing organic residues on the surface of an object to be polished after polishing containing polysilicon. That is, it is preferable the above silicon-containing material contains polysilicon. The reason therefor is as follows: a polysilicon-containing material (polysilicon film) has particularly high hydrophobicity as compared with other silicon-containing materials (silicon nitride film, silicon oxide film), and thus hydrophilicity is more likely to be imparted by a water-soluble polymer or the like, whereby the effect of improving the cleaning effect becomes more remarkable.

### <Surface Treatment Method>

The surface treatment composition according to one mode of the present invention is suitable for use in a surface treatment. That is, according to another mode of the present invention, a surface treatment method including subjecting an object to be polished after polishing to a surface treatment using the above surface treatment composition is also provided. As used herein, a surface treatment method refers to a method for reducing foreign bodies on the surface of an object to be polished after polishing, and is a method of cleaning in a broad sense.

By the surface treatment method according to one mode of the present invention, foreign bodies, such as particles and organic residues, remaining on the surface of an object to be polished after polishing can be efficiently removed. That is, according to another mode of the present invention, a method for reducing foreign bodies on the surface of an object to be polished after polishing, including subjecting an object to be polished after polishing to a surface treatment using the above surface treatment composition, is also provided.

The surface treatment method according to one mode of the present invention is performed by a method in which the above surface treatment composition is brought into direct contact with an object to be polished after polishing.

As surface treatment methods, mainly, a method by a rinse polishing treatment (I) and a method by a cleaning treatment (II) can be mentioned. That is, it is preferable that the surface treatment according to one mode of the present invention is performed by rinse polishing or cleaning. A rinse polishing treatment and a cleaning treatment are performed in order to remove foreign bodies (particles, metallic contaminants, organic residues, pad debris, etc.) on the surface of an object to be polished after polishing, thereby obtaining a clean surface. The above methods (I) and (II) will be described hereinafter.

### (I) Rinse Polishing Treatment

The surface treatment composition according to the present invention is suitable for use in a rinse polishing treatment. That is, as a preferred mode of the present invention, a rinse polishing method, in which a rinse polishing treatment is performed using the above surface treatment composition, is provided. Still another mode of the present invention is a rinse polishing method, in which an object to be polished after polishing containing polysilicon is subjected to a rinse polishing treatment using the above surface treatment composition.

The rinse polishing treatment is performed for the purpose of removing foreign bodies on the surface of an object to be polished after the object to be polished has been subjected to final polishing (finish polishing). The treatment is performed on a polishing table (platen) having attached thereto a polishing pad. At this time, the rinse polishing treatment is performed by bringing the surface treatment composition (rinse composition) into direct contact with the object to be polished after polishing. As a result, foreign bodies on the surface of the object to be polished after polishing are removed by the frictional force of the polishing pad (physical action) and also by the chemical action of the surface treatment composition. Of foreign bodies, particles and organic residues are particularly easy to remove by the physical action. Therefore, in the rinse polishing treatment, particles and organic residues can be effectively removed by utilizing the friction with the polishing pad on the polishing table (platen).

Specifically, the rinse polishing treatment can be performed as follows. After a polishing step, the surface of the object to be polished after polishing is placed on the polishing table (platen) of a polishing device to bring the polishing pad and the polished semiconductor substrate into contact with each other, and, while supplying the surface treatment composition to the region of contact, the object to be polished after polishing and the polishing pad are slid relative to each other.

The rinse polishing treatment can be performed using a one-side polishing device or a double-side polishing device. In addition, it is preferable that the polishing device has a discharge nozzle for a surface treatment composition in addition to a discharge nozzle for a polishing composition. The operating conditions of the polishing device at the time of the rinse polishing treatment are not particularly limited and can be suitably set by a person skilled in the art.

After the above rinse polishing treatment is performed, a cleaning treatment may be further performed. As a result of the cleaning treatment, foreign bodies on the surface of the object to be polished after polishing are further removed. The cleaning method is not particularly limited, and a known technique may be used.

### (II) Cleaning Treatment

The surface treatment composition according to the present invention may be used in a cleaning treatment. The cleaning treatment is performed for the purpose of removing foreign bodies on the surface of an object to be polished after the object to be polished has been subjected to final polishing (finish polishing) or to the above rinse polishing treatment. Incidentally, the cleaning treatment and the above rinse polishing treatment are classified according to the place where the treatment is performed. The cleaning treatment is a surface treatment performed after removing the object to be polished after polishing from the polishing table (platen). Also in the cleaning treatment, the surface treatment composition according to the present invention is brought into direct contact with the object to be polished after polishing, whereby foreign bodies on the surface of the object can be removed.

As methods for performing a cleaning treatment, (i) a method in which, with the object to be polished after polishing being held, a cleaning brush is brought into contact with one side or both sides of the object to be polished after polishing, and, while supplying a surface treatment composition to the region of contact, the surface of the object to be cleaned is rubbed with the cleaning brush; (ii) a method in which the object to be polished after polishing is immersed in a surface treatment composition, and ultrasonically treated or stirred (dip method); and the like can be mentioned. In such a method, foreign bodies on the surface of the object to be polished are removed by the frictional force of the cleaning brush or the mechanical force generated by the ultrasonic treatment or stirring and the chemical action of the surface treatment composition.

In the method (i), the method for bringing a surface treatment composition (cleaning composition) into contact with the object to be polished after polishing is not particularly limited, and may be, for example, a spin method in which the object to be polished after polishing is rotated at a high speed while pouring the surface treatment composition onto the object to be polished after polishing from a nozzle, a spray method in which the object to be polished after polishing is cleaned by spraying the surface treatment composition thereto, or the like.

For the reason that decontamination can be achieved more efficiently within a short period of time, the cleaning treatment is preferably a spin method or a spray method, and more preferably a spin method.

As devices for performing such a cleaning treatment, for example, a batch cleaning device in which a plurality of sheets of an object to be polished after polishing placed in a cassette are simultaneously surface-treated, a single-wafer cleaning device in which one sheet of an object to be polished after polishing is attached to a holder and surface-treated, and the like can be mentioned. Among these, in terms of reducing the cleaning time, for example, a method using a single-wafer cleaning device is preferable.

Further, as a device for performing the cleaning treatment, for example, a polishing device having a cleaning facility, in which the object to be polished after polishing that has been removed from the polishing table (platen) is rubbed with a cleaning brush, can be mentioned. By using such a polishing device, the cleaning treatment of the object to be polished after polishing can be performed more efficiently.

As such a polishing device, a common polishing device having a holder for holding an object to be polished after polishing, a motor capable of changing the rotation speed, a cleaning brush, and the like may be used. The polishing device may be a one-side polishing device or a double-side polishing device. Incidentally, in the case where a rinse polishing step is performed after a CMP step, it is more efficient and preferable that the cleaning treatment is performed using the same device as the polishing device used in the rinse polishing step.

The cleaning brush is not particularly limited, but it is preferable to use a brush made of a resin. Materials for the brush made of a resin are not particularly limited, but it is preferable to use PVA (polyvinyl alcohol), for example. Further, as the cleaning brush, it is particularly preferable to use a sponge made of PVA.

The cleaning conditions are not particularly limited either, and may be suitably set according to the kind of the object to be cleaned and the kind and amount of organic residues to be removed. The method for supplying a surface treatment composition to the polishing pad is not particularly limited either, and a continuous supply method using a pump or the like (pouring) may be employed, for example. The supply rate is not limited, but it is preferable that the surfaces of the cleaning brush and the object to be cleaned are constantly covered with the surface treatment composition, and the supply rate is preferably 10 mL/min or more and 5,000 mL/min or less. The cleaning time is not particularly limited either, but is preferably 5 seconds or more and 180 seconds or less in a step using the surface treatment composition according to one mode of the present invention. Within such a range, foreign bodies can be more effectively removed. The temperature of the surface treatment composition at the time of cleaning is not particularly limited, and may usually be room temperature. However, without impairing the performance, the surface treatment composition may also be warmed to about 40° C. or more and 70° C. or less.

In the method (ii), the conditions of the immersion cleaning method are not particularly limited, and a known technique may be used.

Before, after, or both before and after the cleaning treatment by the method (i) or (ii), water cleaning may be performed.

In addition, it is preferable that the object to be polished after polishing (object to be cleaned) after cleaning is dried by removing water drops adhering to the surface using a spin dryer, for example. In addition, it is also possible that the surface of the object to be cleaned is dried by air-blow drying.

### <Method for Producing Semiconductor Substrate>

The surface treatment method according to one mode of the present invention is suitably applicable when the object to be polished after polishing is a polished semiconductor substrate. That is, according to still another mode of the present invention, a method for producing a semiconductor substrate, wherein the object to be polished after polishing is a polished semiconductor substrate, the method including subjecting the polished semiconductor substrate to a surface treatment using the above surface treatment composition, is also provided. As a yet more preferred mode, a method for producing a semiconductor substrate, including subjecting a polished semiconductor substrate to a rinse polishing treatment using the above surface treatment composition, is also provided.

The details of the semiconductor substrate to which these methods are applied are as described above for the object to be polished after polishing to be subjected to a surface treatment using the above surface treatment composition.

In addition, the method for producing a semiconductor substrate is not particularly limited as long as it includes a step of subjecting the surface of a polished semiconductor substrate to a surface treatment using the surface treatment composition according to the present invention (surface treatment step: rinse polishing step, cleaning step). As such a method, for example, a method including a polishing step for forming a polished semiconductor substrate and a surface treatment step, preferably a method including a polishing step for forming a polished semiconductor substrate and a rinse polishing step, can be mentioned. In addition, as another example, a method including a polishing step, a rinse polishing step, and also a cleaning step after the rinse polishing step can be mentioned. Hereinafter, each of these steps will be described.

### [Polishing Step]

The polishing step that may be included in the method for producing a semiconductor substrate is a step of polishing a semiconductor substrate to form a polished semiconductor substrate.

The polishing step is not particularly limited as long as it is a step of polishing a semiconductor substrate, but is preferably a chemical mechanical polishing (CMP) step. In addition, the polishing step may be a polishing step composed of a single step or a polishing step composed of a plurality of steps.

As the polishing composition, a known polishing composition may be suitably used according to the properties of the semiconductor substrate. The polishing composition is not particularly limited, but it is preferable to use a composition containing abrasive grains, an acid salt, a dispersion medium, and an acid, for example. Specific examples of such polishing compositions include a polishing composition containing sulfonic acid-modified colloidal silica, ammonium sulfate, water, maleic acid, and the like.

As the polishing device, a common polishing device having attached thereto a holder for holding an object to be polished, a motor capable of changing the rotation speed, and the like, and including a polishing table to which a polishing pad (polishing cloth) can be attached, may be used. The polishing device may be a one-side polishing device or a double-side polishing device.

As the polishing pad, common nonwoven fabrics, polyurethane, porous fluororesin, and the like may be used without particular limitations. It is preferable that the polishing pad has formed therein grooves, in which a polishing liquid accumulates.

The polishing conditions are not particularly limited either. For example, the rotation speed of the polishing table and the head (carrier) rotation speed are preferably 10 rpm or more and 100 rpm or less. The pressure applied to the object to be polished (polishing pressure) is preferably 0.5 psi or more and 10 psi or less. The method for supplying a polishing composition to the polishing pad is not particularly limited either, and a continuous supply method using a pump or the like (pouring) may be employed, for example. The supply rate is not limited, but it is preferable that the surface of the polishing pad is constantly covered with the polishing composition, and the supply rate is preferably 10 mL/min or more and 5,000 mL/min or less. The polishing time is not particularly limited either, but is preferably 5 seconds or more and 180 seconds or less in a step using the polishing composition.

### [Surface Treatment Step]

A surface treatment step refers to a step of reducing foreign bodies on the surface of an object to be polished after polishing in the method for producing a semiconductor substrate. In the surface treatment step, it is possible to perform both a rinse polishing step and a cleaning step, and it is also possible to perform only a rinse polishing step or a cleaning step.

The surface treatment composition according the present invention is suitable for use in the surface treatment step. That is, it is preferable that the surface treatment step is a step of reducing foreign bodies on the surface of an object to be polished after polishing using the surface treatment composition according to the present invention. Thus, in the surface treatment step, a rinse polishing step and a cleaning step may be performed using the surface treatment composition according to the present invention. Alternatively, it is also possible that after a rinse polishing step, a cleaning step is performed as a surface treatment step using the surface treatment composition according to the present invention, or that only a cleaning step or a rinse polishing step is performed using the surface treatment composition according to the present invention.

### (Rinse Polishing Step)

A rinse polishing step is performed after the polishing step in the method for producing a semiconductor substrate. The rinse polishing step is a step of reducing foreign bodies on the surface of an object to be polished after polishing (polished semiconductor substrate) by the surface treatment method (rinse polishing method) according to one mode of the present invention.

As the polishing device, devices such as the polishing pad and the polishing conditions, the same devices and conditions as in the above polishing step may be applied, except for supplying the surface treatment composition according to the present invention instead of supplying a polishing composition.

The details of the rinse polishing method used in the rinse polishing step are as described above for the rinse polishing treatment.

### (Cleaning Step)

In the method for producing a semiconductor substrate, a cleaning step may be provided after the polishing step or after the rinse polishing step. The cleaning method used in the cleaning step is not particularly limited, and a known technique is used. The cleaning step is a step of reducing foreign bodies on the surface of an object to be polished after polishing (polished semiconductor substrate) by the surface treatment method (cleaning method) according to one mode of the present invention.

The details of the cleaning method used in the cleaning step are as described above for the cleaning method.

### EXAMPLES

The present invention will be described in further detail through the following examples and comparative examples. However, the technical scope of the present invention is not limited only to the following examples. Incidentally, unless otherwise noted, “%” and “parts” mean “% by mass” and “parts by mass”, respectively.

### <Measurement of Weight Average Molecular Weight>

As the weight average molecular weight (Mw) of each substance, the value of the weight average molecular weight (in terms of polyethylene glycol) measured by gel permeation chromatography (GPC) was used. The weight average molecular weight was measured using the following device under the following conditions.

GPC device: manufactured by Shimadzu Corporation Co., Ltd.

Model: Prominence+ELSD detector (ELSD-LTII)

Column: VP-ODS (manufactured by Shimadzu Corporation Co., Ltd.)

Mobile phase A: MeOH

B: 1% Aqueous acetic acid solution

Flow rate: 1 mL/min

Detector: ELSD temp. 40° C., Gain 8, N₂GAS 350 kPa

Oven temperature: 40° C.

Injection volume: 40 μL

### Preparation of Surface Treatment Composition (Rinse Composition)

### Example 1: Preparation of Surface Treatment Composition A-1

0.0166 parts by mass of hydroxyethyl cellulose (weight average molecular weight: 1,200,000) as a water-soluble polymer, 0.015 parts by mass of sodium polystyrene sulfonate (weight average molecular weight: 20,000) as an anionic surfactant, 0.025 parts by mass of diammonium hydrogen citrate as a pH buffer, suitable amounts of citric acid and ammonia as pH adjusters (i.e., amounts to make pH=8.5), and water (deionized water) in an amount that makes the total 100 parts by mass were mixed, thereby preparing a surface treatment composition A-1. With respect to the surface treatment composition A-1 (liquid temperature: 25° C.), the pH checked using a pH meter (manufactured by HORIBA, Ltd., product name: LAQUA) was 8.5.

### Examples 2 to 3: Preparation of Surface Treatment Compositions A-2 to A-3

Surface treatment compositions A-2 and A-3 were each prepared in the same manner as in Example 1, except that the water-soluble polymer was changed as follows, and the added amount (on a solids basis) was changed to the values shown in Table 1-1:
Example 2: Hydroxyethyl cellulose (weight average molecular weight: 130,000)
Example 3: Hydroxyethyl cellulose (weight average molecular weight: 1,800,000).

### Examples 4 to 5: Preparation of Surface Treatment Compositions A-4 to A-5

Surface treatment compositions A-4 to A-5 were each prepared in the same manner as in Example 1, except that the amount of water-soluble polymer added (on a solids basis) was changed to the values shown in Table 1-1.

### Examples 6 to 13: Preparation of Surface Treatment Compositions A-6 to A-13

Surface treatment compositions A-6 and A-13 were each prepared in the same manner as in Example 1, except that the water-soluble polymer was changed as follows, and the added amount (on a solids basis) was changed to the values shown in Table 1-1:
Example 6: Polyvinyl alcohol (weight average molecular weight: 10,000; saponification degree: about 95%)
Example 7: Polyvinyl alcohol (weight average molecular weight: 100,000; saponification degree: about 95%) and polyvinyl alcohol (weight average molecular weight: 400,000; saponification degree: about 95%)
Example 8: Hydrophilic/alcohol-philic group (ethylene oxide group, etc.)-containing polyvinyl alcohol (manufactured by Nippon Synthetic Chemical Industry Co., Ltd., product name: GOHSENX LW-100; weight average molecular weight: 1,000 or more; saponification degree: about 43%)
Example 9: Acetoacetyl group-containing polyvinyl alcohol (manufactured by Nippon Synthetic Chemical Industry Co., Ltd., product name: GOHSENX Z-100; weight average molecular weight: 1,000 or more; saponification degree: 98.5% or more)
Example 10: Ethylene oxide group-containing polyvinyl alcohol (manufactured by Nippon Synthetic Chemical Industry Co., Ltd., product name: GOHSENX WO-320N; weight average molecular weight: 1,000 or more; saponification degree: 98.5% or more)
Example 11: Butenediol/vinyl alcohol copolymer (manufactured by Nippon Synthetic Chemical Industry Co., Ltd., product name: Nichigo G-Polymer AZF 8035W; weight average molecular weight: 1,000 or more; saponification degree: 95% or more)
Example 12: Polyvinylpyrrolidone (manufactured by DKS Co., Ltd., product name: PITZCOL K-30A; weight average molecular weight: 40,000)
Example 13: Polyvinylpyrrolidone/polyvinyl alcohol copolymer (manufactured by DKS Co., Ltd., product name: PITZCOL V-7154; weight average molecular weight: 1,000 or more)

Incidentally, in Examples 6 and 7, the amount of anionic surfactant added (on a solids basis) was also changed to the value described in Table 1-1.

### Examples 14 to 16: Preparation of Surface Treatment Compositions A-14 to A-16

Surface treatment compositions A-14 to A-16 were each prepared in the same manner as in Example 1, except that the anionic surfactant was changed as follows:
Example 14: Sodium polystyrene sulfonate (weight average molecular weight: 3,000)
Example 15: Sodium polystyrene sulfonate (weight average molecular weight: 1,000,000)
Example 16: Sodium polystyrene sulfonate (weight average molecular weight: 75,000).

### Examples 17 to 18: Preparation of Surface Treatment Compositions A-17 to A-18

Surface treatment compositions A-17 to A-18 were each prepared in the same manner as in Example 1, except that the amount of anionic surfactant added (on a solids basis) was changed to the values shown in Table 1-2.

### Examples 19 to 29: Preparation of Surface Treatment Compositions A-19 to A-29

Surface treatment compositions A-19 to A-29 were each prepared in the same manner as in Example 1, except that the anionic surfactant was changed as follows, and the added amount (on a solids basis) was changed to the values shown in Table 1-2:
Example 19: Sodium polystyrene sulfonate/polystyrene copolymer (5:5) (weight average molecular weight: 19,000)
Example 20: Sodium polystyrene sulfonate/methacrylic acid copolymer (8:2) (weight average molecular weight: 3,400)
Example 21: Sodium polystyrene sulfonate/polymaleic acid copolymer (75:25) (weight average molecular weight: 20,000)
Example 22: Sulfonic acid group-containing polyvinyl alcohol (weight average molecular weight: 20,000)
Example 23: n-Dodecylbenzenesulfonic acid (molecular weight: 326)
Example 24: Alkyl diphenyl ether disulfonic acid ammonium salt (manufactured by Takemoto Oil & Fat Co., Ltd., product name: TAKESURF A-43-NQ; weight average molecular weight: less than 1,000)
Example 25: Sodium polyoxyalkylene allyl phenyl ether sulfate (manufactured by Takemoto Oil & Fat Co., Ltd., product name: New Kargen FS-7S; weight average molecular weight: less than 1,000)
Example 26: Polyoxyethylene alkyl (12-15) ether phosphoric acid (manufactured by Nikko Chemicals Co., Ltd., product name: NIKKOL DDP-6; weight average molecular weight: less than 1,000)
Example 27: Polyoxyethylene allyl phenyl ether phosphate amine salt (manufactured by Takemoto Oil & Fat Co., Ltd., product name: New Kargen FS-3AQ; weight average molecular weight: less than 1,000)
Example 28: Bis (poly-2-carboxyethyl) phosphinic acid (manufactured by BWA, product name: Belsperse 164; weight average molecular weight: less than 1,000)
Example 29: Phosphino polycarboxylic acid copolymer (manufactured by BWA, product name: Belclene 400; weight average molecular weight: 1,000 or more).

### Example 30: Preparation of Surface Treatment Composition A-30

A surface treatment composition A-30 was prepared in the same manner as in Example 1, except that no pH buffer was added.

### Examples 31 to 34: Preparation of Surface Treatment Compositions A-31 to A-34

Surface treatment compositions A-31 to A-34 were each prepared in the same manner as in Example 1, except that the pH buffer, the pH adjusters, and the amounts thereof added (on a solids basis) were changed to the values shown in Table 1-3.

### Comparative Example 1: Preparation of Surface Treatment Composition C-1

A surface treatment composition C-1 was prepared in the same manner as in Example 1, except that the anionic surfactant was changed to polyacrylic acid, and the amount thereof added (on a solids basis) was changed to the value shown in Table 1-3.

### Comparative Example 2: Preparation of Surface Treatment Composition C-2

A surface treatment composition C-2 was prepared in the same manner as in Example 1, except that no anionic surfactant was added.

### Comparative Example 3: Preparation of Surface Treatment Composition C-3

A surface treatment composition C-3 was prepared in the same manner as in Example 1, except that no anionic surfactant and no pH buffer were added.

### Comparative Example 4: Preparation of Surface Treatment Composition C-4

A surface treatment composition C-4 was prepared in the same manner as in Example 1, except that no water-soluble polymer was added.

### Examples 35 to 37: Preparation of Surface Treatment Compositions A-35 to A-37

Surface treatment compositions A-35 to A-37 were each prepared in the same manner as in Example 1, except that the pH adjusters were added to make the pH of the surface treatment composition 6.0, 7.5, or 10.2.

### Comparative Examples 5 to 7: Preparation of Surface Treatment Compositions C-5 to C-7

Surface treatment compositions C-5 to C-7 were each prepared in the same manner as in Example 1, except that no anionic surfactant was added, and the pH adjusters were added to make the pH of the surface treatment composition 6.0, 7.5, or 10.0.

### <Evaluation>

### [Evaluation of the Number of Foreign Bodies]

(Preparation of Object to be Polished after Polishing (Object to be Rinse Polished)

A polished polysilicon substrate that had been polished by the following chemical mechanical polishing (CMP) step was prepared as an object to be polished after polishing.

### <<CMP Step>>

A polysilicon substrate was polished using a polishing composition M (composition: 3 mass % of sulfonic acid-modified colloidal silica (produced by the method described in “Sulfonic acid-functionalized silica through quantitative oxidation of thiol groups”, Chem. Commun. 246-247 (2003), primary particle size: 30 nm, secondary particle size: 60 nm), 0.1 mass % of polyethylene glycol (molecular weight: 400), solvent: water, adjusted to pH=2 with 60% nitric acid) under the following conditions.

### —Polishing Device and Polishing Conditions—

Object to be polished: 200-mm Polysilicon wafer

Polishing device: One-side polishing device for 200-mm wafers

Polishing pad: Pad made of polyurethane foam (hardness: 90)

Polishing pressure: 2.3 psi (1 psi=6,894.76 Pa; the same hereinafter)

Polishing table rotation speed: 93 rpm

Supply of polishing composition: Pouring

Supply rate of polishing composition: 100 mL/min

Head rotation speed: 87 rpm

Polishing time: 60 seconds.

### <<Rinse Polishing Step>>

Following the above CMP step, the polysilicon substrate that had been polished in the above step was subjected to a rinse polishing treatment using each surface treatment composition (rinse composition) prepared above.

### —Rinse Polishing Device and Rinse Polishing Conditions—

Rinse polishing device: One-side polishing device for 200-mm wafers

Polishing pad: Pad made of polyurethane foam (hardness: 90)

Polishing pressure: 1.5 psi

Polishing table rotation speed: 88 rpm

Supply of surface treatment composition (rinse composition): Pouring

Supply rate of surface treatment composition (rinse composition): 100 mL/min

Head rotation speed: 85 rpm

Rinse polishing time: 10 seconds.

### <<Cleaning Step>>

Following the above rinse polishing step, the polysilicon substrate that had been rinse polished was rubbed for 60 seconds under pressure with a PVA sponge while pouring water onto the wafer.

### <<Measurement of the Number of Foreign Bodies>>

With respect to each polysilicon substrate cleaned in the above cleaning step, the number of foreign bodies (particles and organic residues) was measured as follows.

First, the number of foreign bodies of 0.13 μm or more was measured. For measuring the number of foreign bodies, SP-2 manufactured by KLA TENCOR was used. In the measurement, a 5-mm-wide portion from the peripheral edge on one side of each substrate was excluded, and the remaining portion was subjected to the measurement.

Next, the number of organic residues was measured. The number of organic residues was measured by SEM observation using Review SEM RS6000 manufactured by Hitachi, Ltd. Specifically, first, by SEM observation, a 5-mm-wide portion from the peripheral edge on one side of each substrate was excluded, and 100 foreign bodies present in the remaining portion were sampled. Subsequently, from the sampled 100 foreign bodies, organic residues were visually distinguished by SEM observation, and the number thereof was checked to calculate the proportion (%) of organic residues in the foreign bodies. Then, the product of the number of foreign bodies of 0.13 μm or more measured in the evaluation of the number of foreign bodies described above and the proportion (%) of organic residues in the foreign bodies calculated above by SEM observation was calculated as the number of organic residues.

Further, from the number of foreign bodies of 0.13 μm or more, the number of organic residues calculated above was subtracted, and the difference was taken as the number of particles. Incidentally, in Comparative Example 4, no significant number of particles was measurable.

The evaluation results are shown in Table 1-1 to Table 1-3 and Table 2 to Table 4. In addition, the pH of each surface treatment composition (rinse composition) is also shown in the tables. Incidentally, with respect to the molecular weights (weight average molecular weights) of the compounds of Group A and Group B, “-” in the tables indicates that no measurement was performed. In addition, in “Group A/Group B (mass ratio)”, the mass ratio of the water-soluble polymer to the anionic surfactant in the surface treatment composition (rinse composition) is shown.

TABLE 1-1

| | | | | | | | Group |
|---|---|---|---|---|---|---|---|
| | Group A | | | Group B | | | A/Group |
| | | Molecular | Content | | Molecular | Content | B (mass |
| | Kind | weight | [mass %] | Kind | weight | [mass %] | ratio) |
| Example 1 | HEC | 1,200,000 | 0.0166 | Polystyrene sulfonic | 20,000 | 0.015 | 1.11 |
| | | | | acid salt (PS-1) | | | |
| Example 2 | HEC | 130,000 | 0.0250 | ↑ | ↑ | ↑ | 1.67 |
| Example 3 | HEC | 1,800,000 | 0.0100 | ↑ | ↑ | ↑ | 0.67 |
| Example 4 | HEC | 1,200,000 | 0.0010 | ↑ | ↑ | ↑ | 0.07 |
| Example 5 | ↑ | ↑ | 0.1000 | ↑ | ↑ | ↑ | 6.67 |
| Example 6 | PVOH | 10,000 | 1.00 | ↑ | ↑ | 0.2 | 5.00 |
| Example 7 | PVOH | 100,000 | 0.075 | ↑ | ↑ | ↑ | 0.75 |
| | PVOH | 400,000 | 0.075 | | | | |
| Example 8 | Hydrophilic/alcohol-philic | 1,000 or more | 0.500 | ↑ | ↑ | 0.015 | 33.33 |
| | group-containing PVOH | | | | | | |
| Example 9 | Acetoacetyl | 1,000 or more | 0.500 | ↑ | ↑ | ↑ | 33.33 |
| | group-containing PVOH | | | | | | |
| Example 10 | Ethylene oxide | 1,000 or more | 0.500 | ↑ | ↑ | ↑ | 33.33 |
| | group-containing PVOH | | | | | | |
| Example 11 | Butenediol/vinyl | 1,000 or more | 0.500 | ↑ | ↑ | ↑ | 33.33 |
| | alcohol copolymer | | | | | | |
| Example 12 | PVP | 40,000 | 1.00 | ↑ | ↑ | ↑ | 66.67 |
| Example 13 | PVP/PVOH copolymer | 1,000 or more | 0.500 | ↑ | ↑ | ↑ | 33.33 |

| | | | | | Number of foreign bodies | | |
|---|---|---|---|---|---|---|---|
| | pH buffer | | | | | Number of | |
| | | Content | pH adjuster | | Number of | organic | Total |
| | Kind | [mass %] | Kind | pH | particles | residues | number |
| Example 1 | Diammonium | 0.025 | Citric | 8.5 | 1 | 15 | 16 |
| | hydrogen | | acid/ammonia | | | | |
| | citrate | | | | | | |
| Example 2 | ↑ | ↑ | ↑ | ↑ | 4 | 20 | 24 |
| Example 3 | ↑ | ↑ | ↑ | ↑ | 3 | 21 | 24 |
| Example 4 | ↑ | ↑ | ↑ | ↑ | 3 | 17 | 20 |
| Example 5 | ↑ | ↑ | ↑ | ↑ | 2 | 20 | 22 |
| Example 6 | ↑ | ↑ | ↑ | ↑ | 3 | 18 | 21 |
| Example 7 | ↑ | ↑ | ↑ | ↑ | 4 | 14 | 18 |
| Example 8 | ↑ | ↑ | ↑ | ↑ | 4 | 16 | 20 |
| Example 9 | ↑ | ↑ | ↑ | ↑ | 5 | 18 | 23 |
| Example 10 | ↑ | ↑ | ↑ | ↑ | 3 | 16 | 19 |
| Example 11 | ↑ | ↑ | ↑ | ↑ | 4 | 20 | 24 |
| Example 12 | ↑ | ↑ | ↑ | ↑ | 3 | 12 | 15 |
| Example 13 | ↑ | ↑ | ↑ | ↑ | 8 | 17 | 25 |

TABLE 1-2

| | | | | | | | Group |
|---|---|---|---|---|---|---|---|
| | Group A | | | Group B | | | A/Group |
| | | Molecular | Content | | Molecular | Content | B (mass |
| | Kind | weight | [mass %] | Kind | weight | [mass %] | ratio) |
| Example 14 | HEC | 1,200,000 | 0.0166 | Polystyrene sulfonic | 3,000 | 0.015 | 1.11 |
| | (CF-W) | | | acid salt | | | |
| Example 15 | ↑ | ↑ | ↑ | Polystyrene sulfonic | 1,000,000 | 0.015 | 1.11 |
| | | | | acid salt | | | |
| Example 16 | ↑ | ↑ | ↑ | Polystyrene sulfonic | 75,000 | 0.015 | 1.11 |
| | | | | acid salt | | | |
| Example 17 | ↑ | ↑ | ↑ | Polystyrene sulfonic | 20,000 | 0.001 | 16.60 |
| | | | | acid salt | | | |
| Example 18 | ↑ | ↑ | ↑ | ↑ | ↑ | 0.100 | 0.17 |
| Example 19 | ↑ | ↑ | ↑ | Polystyrene sulfonic acid salt/ | 19,000 | 0.015 | 1.11 |
| | | | | polystyrene copolymer (5:5) | | | |
| Example 20 | ↑ | ↑ | ↑ | Polystyrene sulfonic acid salt/ | 3,400 | 0.015 | 1.11 |
| | | | | methacrylic acid copolymer (8:2) | | | |
| Example 21 | ↑ | ↑ | ↑ | Polystyrene sulfonic acid salt/ | 20,000 | 0.015 | 1.11 |
| | | | | polymaleic acid copolymer (75:25) | | | |
| Example 22 | ↑ | ↑ | ↑ | Sulfonic acid group-containing | 20,000 | 0.015 | 1.11 |
| | | | | PVOH | | | |
| Example 23 | ↑ | ↑ | ↑ | n-Dodecylbenzenesulfonic acid | 326 | 0.015 | 1.11 |
| Example 24 | ↑ | ↑ | ↑ | Alkyl diphenyl ether disulfonic | Less than 1,000 | 0.100 | 0.17 |
| | | | | acid salt | | | |
| Example 25 | ↑ | ↑ | ↑ | Polyoxyalkylene allyl phenyl | Less than 1,000 | 0.100 | 0.17 |
| | | | | ether sulfuric acid salt | | | |
| Example 26 | ↑ | ↑ | ↑ | Polyoxyethylene alkyl (12-25) | Less than 1,000 | 0.100 | 0.17 |
| | | | | ether phosphoric acid | | | |
| Example 27 | ↑ | ↑ | ↑ | Polyoxyethylene allyl phenyl | Less than 1,000 | 0.100 | 0.17 |
| | | | | ether phosphoric acid salt | | | |
| Example 28 | ↑ | ↑ | ↑ | Bis(poly-2-carboxyethyl) | Less than 1,000 | 0.100 | 0.17 |
| | | | | phosphinic acid | | | |
| Example 29 | ↑ | ↑ | ↑ | Phosphino polycarboxylic | 1,000 or more | 0.100 | 0.17 |
| | | | | acid copolymer | | | |

| | | | | | Number of foreign bodies | | |
|---|---|---|---|---|---|---|---|
| | pH buffer | | | | | Number of | |
| | | Content | pH adjuster | | Number of | organic | Total |
| | Kind | [mass %] | Kind | pH | particles | residues | number |
| Example 14 | Diammonium | 0.025 | Citric | 8.5 | 2 | 18 | 20 |
| | hydrogen | | acid/ammonia | | | | |
| | citrate | | | | | | |
| Example 15 | ↑ | ↑ | ↑ | ↑ | 1 | 14 | 15 |
| Example 16 | ↑ | ↑ | ↑ | ↑ | 3 | 16 | 19 |
| Example 17 | ↑ | ↑ | ↑ | ↑ | 4 | 16 | 20 |
| Example 18 | ↑ | ↑ | ↑ | ↑ | 1 | 18 | 19 |
| Example 19 | ↑ | ↑ | ↑ | ↑ | 0 | 18 | 18 |
| Example 20 | ↑ | ↑ | ↑ | ↑ | 4 | 20 | 24 |
| Example 21 | ↑ | ↑ | ↑ | ↑ | 2 | 18 | 20 |
| Example 22 | ↑ | ↑ | ↑ | ↑ | 3 | 14 | 17 |
| Example 23 | ↑ | ↑ | ↑ | ↑ | 3 | 21 | 24 |
| Example 24 | ↑ | ↑ | ↑ | ↑ | 3 | 16 | 19 |
| Example 25 | ↑ | ↑ | ↑ | ↑ | 2 | 19 | 21 |
| Example 26 | ↑ | ↑ | ↑ | ↑ | 3 | 18 | 21 |
| Example 27 | ↑ | ↑ | ↑ | ↑ | 2 | 20 | 22 |
| Example 28 | ↑ | ↑ | ↑ | ↑ | 2 | 14 | 16 |
| Example 29 | ↑ | ↑ | ↑ | ↑ | 1 | 13 | 14 |

TABLE 1-3

| | | | | | | | Group | |
|---|---|---|---|---|---|---|---|---|
| | Group A | | | Group B | | | A/Group | |
| | | Molecular | Content | | Molecular | Content | B (mass | pH buffer |
| | Kind | weight | [mass %] | Kind | weight | [mass %] | ratio) | Kind |
| Example 30 | HEC | 1,200,000 | 0.0166 | Polystyrene sulfonic | 20,000 | 0.015 | 1.11 | — |
| | | | | acid salt | | | | |
| Example 31 | ↑ | ↑ | ↑ | ↑ | ↑ | ↑ | ↑ | Diammonium |
| | | | | | | | | hydrogen |
| | | | | | | | | citrate |
| Example 32 | ↑ | ↑ | ↑ | ↑ | ↑ | ↑ | ↑ | Trishydroxymethyl |
| | | | | | | | | aminomethane (/citric acid) |
| Example 33 | ↑ | ↑ | ↑ | ↑ | ↑ | ↑ | ↑ | Dipotassium hydrogen phosphate |
| Example 34 | ↑ | ↑ | ↑ | ↑ | ↑ | ↑ | ↑ | Iminodiacetic acid |
| | | | | | | | | (/2-amino-2-ethyl-1,3-propanediol) |
| Comparative | ↑ | ↑ | ↑ | Polyacrylic acid | 200,000 | 0.100 | 0.17 | Diammonium |
| Example 1 | | | | | | | | hydrogen |
| | | | | | | | | citrate |
| Comparative | ↑ | ↑ | ↑ | — | — | — | — | ↑ |
| Example 2 | | | | | | | | |
| Comparative | ↑ | ↑ | ↑ | — | — | — | — | — |
| Example 3 | | | | | | | | |
| Comparative | — | — | — | Polystyrene sulfonic | 20,000 | 0.015 | — | Diammonium |
| Example 4 | | | | acid salt (PS-1) | | | | hydrogen |
| | | | | | | | | citrate |

| | | | | Number of foreign bodies | | |
|---|---|---|---|---|---|---|
| | pH buffer | | | | Number of | |
| | Content | pH adjuster | | Number of | organic | Total |
| | [mass %] | Kind | pH | particles | residues | number |
| Example 30 | — | Citric | 8.5 | 1 | 16 | 17 |
| | | acid/ammonia | | | | |
| Example 31 | 0.500 | ↑ | ↑ | 2 | 12 | 14 |
| Example 32 | 0.025 | ↑ | ↑ | 0 | 17 | 17 |
| | (*2) | | | | | |
| Example 33 | 0.025 | Phosphoric acid/potassium | ↑ | 2 | 19 | 21 |
| | | hydroxide | | | | |
| Example 34 | 0.025 | 2-Amino-2-ethyl-1,3-propanediol | ↑ | 1 | 15 | 16 |
| | (*3) | | | | | |
| Comparative | 0.025 | Citric | ↑ | 27 | 520 | 547 |
| Example 1 | | acid/ammonia | | | | |
| Comparative | ↑ | ↑ | ↑ | 1 | 27 | 28 |
| Example 2 | | | | | | |
| Comparative | — | ↑ | ↑ | 3 | 29 | 32 |
| Example 3 | | | | | | |
| Comparative | 0.025 | ↑ | ↑ | *1 | >10000 | >10000 |
| Example 4 | | | | | | |

*1: The number of particles was unmeasurable.
(*2): The content of trishydroxymethyl aminomethane is shown.
(*3): The content of iminodiacetic acid is shown.

TABLE 2

| | | | | | | | Group |
|---|---|---|---|---|---|---|---|
| | Group A | | | Group B | | | A/Group |
| | | Molecular | Content | | Molecular | Content | B (mass |
| | Kind | weight | [mass %] | Kind | weight | [mass %] | ratio) |
| Example 35 | HEC | 1,200,000 | 0.0166 | Polystyrene sulfonic | 20,000 | 0.015 | 1.11 |
| | | | | acid salt | | | |
| Comparative | ↑ | ↑ | ↑ | — | — | — | — |
| Example 5 | | | | | | | |

| | | | | | Number of foreign bodies | | |
|---|---|---|---|---|---|---|---|
| | pH buffer | | | | | Number of | |
| | | Content | pH adjuster | | Number of | organic | Total |
| | Kind | [mass %] | Kind | pH | particles | residues | number |
| Example 35 | Diammonium | 0.025 | Citric | 6.0 | 10 | 32 | 42 |
| | hydrogen | | acid/ammonia | | | | |
| | citrate | | | | | | |
| Comparative | ↑ | ↑ | ↑ | ↑ | 12 | 56 | 68 |
| Example 5 | | | | | | | |

TABLE 3

| | | | | | | | Group |
|---|---|---|---|---|---|---|---|
| | Group A | | | Group B | | | A/Group |
| | | Molecular | Content | | Molecular | Content | B (mass |
| | Kind | weight | [mass %] | Kind | weight | [mass %] | ratio) |
| Example 36 | HEC | 1,200,000 | 0.0166 | Polystyrene sulfonic | 20,000 | 0.015 | 1.11 |
| | | | | acid salt | | | |
| Comparative | ↑ | ↑ | ↑ | — | — | — | — |
| Example 6 | | | | | | | |

| | | | | | Number of foreign bodies | | |
|---|---|---|---|---|---|---|---|
| | pH buffer | | | | | Number of | |
| | | Content | pH adjuster | | Number of | organic | Total |
| | Kind | [mass %] | Kind | pH | particles | residues | number |
| Example 36 | Diammonium | 0.025 | Citric | 7.5 | 6 | 16 | 22 |
| | hydrogen | | acid/ammonia | | | | |
| | citrate | | | | | | |
| Comparative | ↑ | ↑ | ↑ | ↑ | 3 | 40 | 43 |
| Example 6 | | | | | | | |

TABLE 4

| | | | | | | | Group |
|---|---|---|---|---|---|---|---|
| | Group A | | | Group B | | | A/Group |
| | | Molecular | Content | | Molecular | Content | B (mass |
| | Kind | weight | [mass %] | Kind | weight | [mass %] | ratio) |
| Example 37 | HEC | 1,200,000 | 0.0166 | Polystyrene sulfonic | 20,000 | 0.015 | 1.11 |
| | | | | acid salt | | | |
| Comparative | ↑ | ↑ | ↑ | — | — | — | — |
| Example 7 | | | | | | | |

| | | | | | Number of foreign bodies | | |
|---|---|---|---|---|---|---|---|
| | pH buffer | | | | | Number of | |
| | | Content | pH adjuster | | Number of | organic | Total |
| | Kind | [mass %] | Kind | pH | particles | residues | number |
| Example 37 | Diammonium | 0.025 | Citric | 10.2 | 2 | 1 | 3 |
| | hydrogen | | acid/ammonia | | | | |
| | citrate | | | | | | |
| Comparative | ↑ | ↑ | ↑ | 10.0 | 3 | 4 | 7 |
| Example 7 | | | | | | | |

The results in the above tables show that by using the surface treatment composition according to one mode of the present invention, the number of foreign bodies on the surface of the object to be polished after polishing was extremely reduced. In addition, from the comparison of Examples 1, 35, 36, and 37, it is also shown that with an increase in the pH value (i.e., with an increase in the alkalinity of the surface treatment composition), the foreign body removing effect also increases.

Further, this application is based on Japanese Patent Application No. 2016-190375 filed on Sep. 28, 2016, the contents of which are entirely incorporated herein by reference.

1: A surface treatment composition comprising:
at least one water-soluble polymer selected from the following Group A;
at least one anionic surfactant selected from the following Group B; and
water:
Group A: water-soluble polysaccharides, polyvinyl alcohols and derivatives thereof, and polyvinylpyrrolidones and derivatives thereof (with the proviso that compounds included in the following Group B are excluded)
Group B: compounds having a sulfonic acid (salt) group, compounds having a sulfuric acid ester (salt) group, compounds having a phosphonic acid (salt) group, compounds having a phosphoric acid (salt) group, and compounds having a phosphinic acid (salt) group.

2: The surface treatment composition according to claim 1, wherein the anionic surfactant selected from the Group B includes at least one member selected from the group consisting of sulfonic (salt) acid group-containing polystyrenes and sulfonic acid (salt) group-containing polyvinyl alcohols.

3: The surface treatment composition according to claim 1, wherein the water-soluble polymer selected from the Group A includes at least one member selected from the group consisting of cellulose derivatives and starch derivatives.

4: The surface treatment composition according to claim 1, having a pH of 4 or more and 12 or less.

5: The surface treatment composition according to claim 1, further comprising a pH buffer.

6: The surface treatment composition according to claim 5, wherein the pH buffer includes at least one member selected from the group consisting of phosphoric acid, succinic acid, tartaric acid, itaconic acid, citric acid, maleic acid, malic acid, and iminodiacetic acid, as well as potassium salts, ammonium salts, and amine salts thereof; and trishydroxymethyl aminomethane, 2-amino-2-ethyl-1,3-propanediol, and diglycolamine, as well as phosphoric acid salts and carboxylic acid salts thereof.

7: The surface treatment composition according to claim 1, wherein the mass ratio of the water-soluble polymer selected from the Group A to the anionic surfactant selected from the Group B is 0.70 or more and 2 or less.

8: The surface treatment composition according to claim 1, comprising substantially no abrasive grains.

9: The surface treatment composition according to claim 1, for use in the rinse polishing of a silicon-containing material.

10: The surface treatment composition according to claim 9, wherein the silicon-containing material contains polysilicon.

11: A method for producing the surface treatment composition according to claim 1, comprising mixing:
at least one water-soluble polymer selected from the following Group A;
at least one anionic surfactant selected from the following Group B; and
water:
Group A: water-soluble polysaccharides, polyvinyl alcohols and derivatives thereof, and polyvinylpyrrolidones and derivatives thereof (with the proviso that compounds included in the following Group B are excluded)
Group B: compounds having a sulfonic acid (salt) group, compounds having a sulfuric acid ester (salt) group, compounds having a phosphonic acid (salt) group, compounds having a phosphoric acid (salt) group, and compounds having a phosphinic acid (salt) group.

12: A surface treatment method, comprising subjecting an object to be polished after polishing to a surface treatment using the surface treatment composition according to claim 1.

13: The surface treatment according to claim 12, wherein the surface treatment method is performed by rinse polishing or cleaning.
